(19) United States
(12) Patent Application Publication
(10) Pub. No.: US 2026/0028206 A1
(43) Pub. Date: Jan. 29, 2026

(54) Transport Facility

(71) Applicant: Daifuku Co., Ltd., Osaka-shi (JP)

(72) Inventor: Yoshitaka Tanaka, Hinocho (JP)

(21) Appl. No.: 19/280,277

(22) Filed: Jul. 25, 2025

(30) Foreign Application Priority Data
Jul. 26, 2024 (JP) 2024-121003

(51) Int. Cl. B66C 13/48; B60L 13/00; B60L 53/35; B60L 58/12; B66C 19/00; G05D 1/698; G05D 105/28; G05D 107/70; H01L 21/67; H01L 21/677

(52) U.S. Cl. CPC B66C 13/48; B60L 13/006; B60L 53/35; B60L 58/12; B66C 19/00; G05D 1/6987; H01L 21/67276; H01L 21/67724; H01L 21/6773; H01L 21/67733; H01L 21/67736; B60L 2200/26; G05D 2105/28; G05D 2107/70

(57) ABSTRACT

A transport facility includes a plurality of transport vehicles that travel in a travel area to transport articles, and a control system that controls the plurality of transport vehicles. The travel area includes a plurality of rechargeable points for recharging the plurality of transport vehicles, and a plurality of transfer points at each of which the plurality of transport vehicles transfer the articles. The control system performs a relay transport process. In the relay transport process, a relay point is selected from the plurality of transfer points, and a recharge point for recharging a first transport vehicle is selected from the plurality of rechargeable points. The relay point is a transfer point closest to the unload point on a transport path of the transport vehicle. The recharge point is selected from rechargeable points of the plurality of rechargeable points within a selection range from the relay point.

### CROSS-REFERENCE TO RELATED APPLICATION

This application claims priority to Japanese Patent Application No. 2024-121003 filed Jul. 26, 2024, the disclosure of which is hereby incorporated by reference in its entirety.

### BACKGROUND OF THE INVENTION

### Field of the Invention

The present invention relates to a transport facility including multiple transport vehicles that travel in a travel area to transport articles and a control system that controls the transport vehicles.

### Description of Related Art

An example of such a transport facility is described in International Publication No. WO 2023/079797 (WO 2023/079797). In the background described below, reference signs and names in parentheses are the reference signs and the names in Patent Literature 1.

A transport facility (transport system 1) described in WO 2023/079797 includes multiple transport vehicles (carriages 6) that travel on a travel path (track 2) to transport articles (26) and a control system (controller 10). The control system (controller 10) controls the multiple transport vehicles (carriages 6) to travel along a transport path (travel route) defined on the travel path (track 2). The transport path (travel route) is defined to efficiently transport the articles (26) across the entire transport facility (transport system 1).

However, in the transport facility (transport system 1) described in WO 2023/079797, the multiple transport vehicles (carriages 6) receive electric power through contactless power feeding. The transport path (travel route) is thus defined without reflecting the travel of transport vehicles (carriages 6) that travel on electric power stored in their power storages. Such transport vehicles (carriages 6) cannot travel without sufficient electric power in their power storages. Thus, the transport path (travel route) is to be defined for each transport vehicle (carriages 6) to travel within the electric power stored in its power storage. When the transport path (travel route) is defined as described in WO 2023/079797, the transport facility including the transport vehicles (carriages 6) that travel on electric power stored in their power storages may not have higher transport efficiency across the entire transport facility.

### SUMMARY OF THE INVENTION

Techniques are awaited for facilitating efficient transportation of articles across the entire facility with a structure including transport vehicles that travel on electric power stored in their power storages.

In response to the above issue, the technique described below is provided.

A transport facility includes a plurality of transport vehicles that travel in a travel area to transport articles, and a control system that controls the plurality of transport vehicles. Each of the plurality of transport vehicles includes a power storage to travel on electric power stored in the power storage. The travel area includes a plurality of rechargeable points and a plurality of Each of the plurality of rechargeable points includes a charger that charges the transfer points. power storage. Each of the plurality of transfer points includes a transfer port at which the plurality of transport vehicles transfer the articles. The control system performs a transport command process, a relay transport process, and a takeover transport process. The transport command process generates, to transport a target article being one of the articles, a transport task specifying a load point at which the target article is loaded and an unload point at which the target article is unloaded, and assigns the transport task to a first transport vehicle among the plurality of transport vehicles. The relay transport process selects a relay point from the plurality of transfer points in response to determining that a battery level of the power storage in the first transport vehicle is insufficient for the first transport vehicle to reach the unload point, selects, from the plurality of rechargeable points, a recharge point at which the power storage in the first transport vehicle is recharged, and causes the first transport vehicle to travel to the relay point and transfer the target article to the transfer port at the relay point. The takeover transport process selects, from the plurality of transport vehicles, a second transport vehicle different from the first transport vehicle in response to the relay point being selected, and causes the second transport vehicle to travel to the relay point, receive the target article from the transfer port at the relay point, and then travel to the unload point. In the relay transport process, the control system selects, as the relay point, a transfer point satisfying a condition that the first transport vehicle reaches the recharge point through the relay point with the battery level of the power storage in the first transport vehicle and being closest to the unload point on a transport path being a travel path of a transport vehicle of the plurality of transport vehicles from the load point to the unload point.

In this structure, when the battery level of the power storage in the transport vehicle performing the transport task is insufficient for the single transport vehicle to transport the target article to the unload point, the target article can be transported to the unload point with multiple transport vehicles. This structure also allows the first transport vehicle to fully use the electric power stored in the power storage in the first transport vehicle to transport the target article as close to the unload point as possible. This allows the second transport vehicle to save the consumption of the electric power stored in its power storage, facilitating efficient transportation of the articles across the entire transport facility.

Further features and advantages of the technique according to the disclosure will be apparent from exemplary and nonlimiting embodiments described below with reference to the drawings.

### BRIEF DESCRIPTION OF THE DRAWINGS

FIG. 1 is a diagram of an example layout of a transport facility according to an embodiment.

FIG. 2 is a side view of an example transport vehicle.

FIG. 3 is a front view of the example transport vehicle.

FIG. 4 is a control block diagram in the embodiment.

FIG. 5 is a diagram describing a relay transport process.

FIG. 6 is a diagram describing a takeover transport process.

FIG. 7 is a diagram describing an example relay transport process 1.

FIG. 8 is a diagram describing an example relay transport process 2.

FIG. 9 is a diagram describing an example relay transport process 3.

FIG. 10 is a diagram describing an example relay transport process 4.

### DESCRIPTION OF THE INVENTION

### 1. Overview of Transport Facility

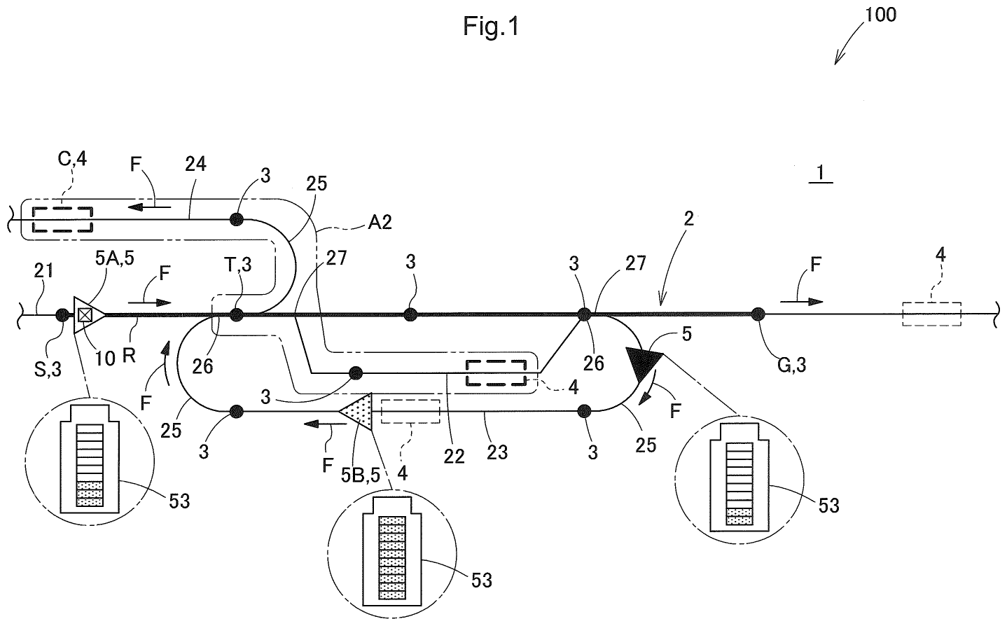

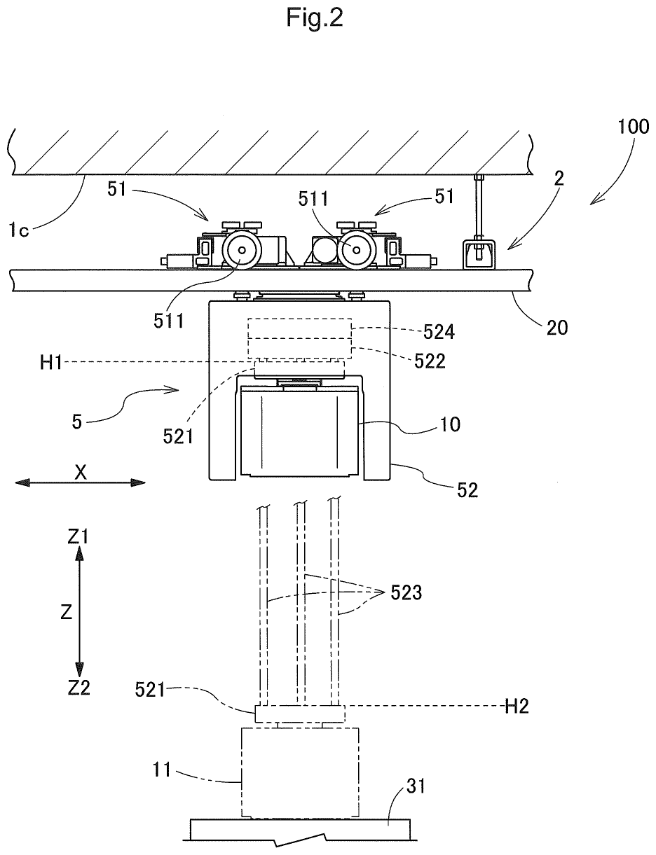

A transport facility 100 according to the present embodiment will be described with reference to the drawings. As shown in FIGS. 1 and 4, the transport facility 100 includes multiple transport vehicles 5 that travel in a travel area 1 to transport articles 11 (refer to FIG. 2), and a control system 6 that controls the transport vehicles 5. The various technical features of the control system 6 described herein are applicable to a method for controlling the transport vehicles 5 and a program for controlling the transport vehicles 5 (a program for causing a computer to function as the control system 6). The method, the program, and a storage medium (e.g., a computer-readable recording medium such as an optical disc or a flash memory) storing the program are also described herein. The articles 11 are, for example, front-opening unified pods (FOUPs) containing semiconductor wafers.

### 2. Travel Area

The travel area 1 includes a travel path 2 along which the transport vehicles 5 can travel, multiple transfer points 3 at which the articles 11 transported by the transport vehicles 5 can be transferred, and multiple rechargeable points 4 at which power storages 53 (described in detail later) in the transport vehicles 5 can be recharged. The travel area 1 may be, for example, a warehouse for storing the articles 11, a finished product assembly plant for assembling the transported articles 11 to manufacture finished products, or a processing plant for performing various processes on the transported articles 11 to manufacture finished products.

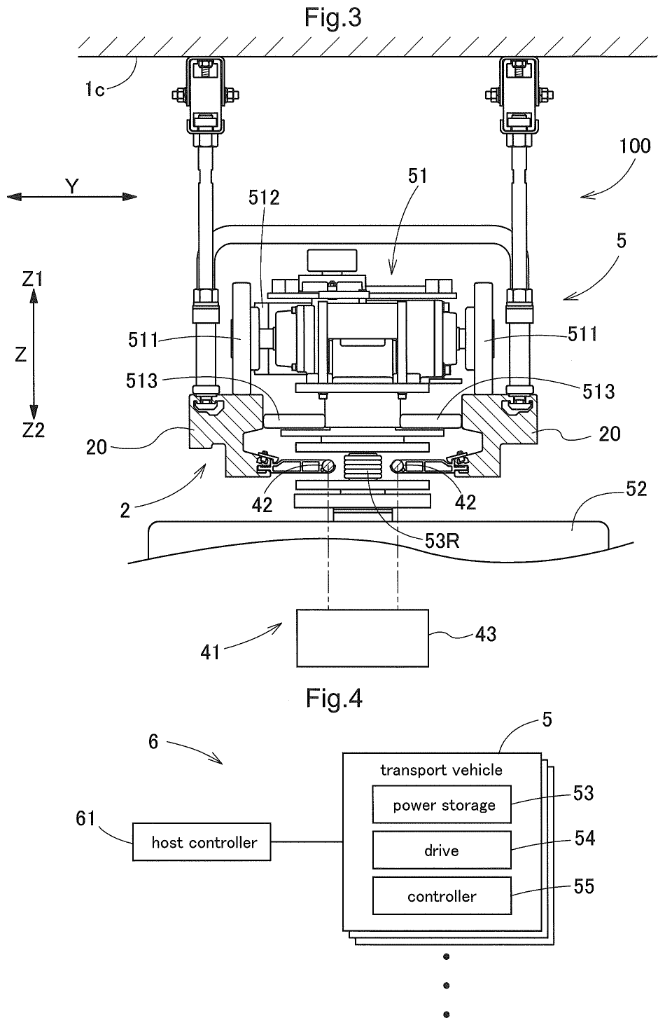

In the present embodiment, the travel path 2 is physically defined. The transport vehicle 5 shown in FIGS. 2 and 3 is a tracked transport vehicle. In this example, the travel path 2 is physically defined with a pair of rails 20 arranged to be spaced from and parallel to each other. In the example in FIGS. 2 and 3, the rails 20 defining the travel path 2 are hung from a ceiling 1c. Thus, in this example, the transport vehicles 5 are ceiling-hung transport vehicles that travel along the travel path 2 disposed along the ceiling 1c. A forward direction F is defined for different portions of the travel path 2 shown in FIG. 1. For the transport vehicles 5, traveling in the forward direction F may be referred to as traveling downstream, and traveling in the direction opposite to the forward direction F may be referred to as traveling upstream. In the examples described below, the transport vehicles 5 travel simply from upstream to downstream in the forward direction F on each portion of the travel path 2 for ease of explanation. However, the transport vehicles 5 may also travel from downstream to upstream in forward direction F on each portion of the travel path 2.

The travel path 2 includes straight portions being straight paths, curved portions 25 being curved paths, junctions 26 at which multiple paths merge into a single path, and branches 27 at which a single path branches into multiple paths. The travel path 2 herein refers to a full portion of the path along which the transport vehicles 5 travel. The travel path 2 is a set of multiple paths (point-to-point paths connecting points). As shown in FIGS. 1 to 3, a direction in which the transport vehicles 5 travel and the travel path 2 extends (a direction in which the rails 20 extend in this example) is referred to as the front-rear direction X, and a direction perpendicular to both the front-rear direction X and the vertical direction Z is referred to as the lateral direction Y. As shown in FIGS. 2 and 3, the pair of rails 20 are spaced from each other in the lateral direction Y.

In the example shown in FIG. 1, the travel path 2 includes, among the straight portions, a primary straight portion 21, a secondary straight portion 22 in a portion branching from the primary straight portion 21, and a return straight portion 23 in a portion branching from the primary straight portion 21. The forward direction F for the secondary straight portion 22 is the same direction as for the primary straight portion 21. The secondary straight portion 22 prevents, for example, the multiple transport vehicles 5 from concentrating on the primary straight portion 21. The return straight portion 23 is a straight portion branching from the primary straight portion 21. The forward direction F for the return straight portion 23 is opposite to the forward direction F for the primary straight portion 21. The return straight portion 23 returns, for example, the transport vehicle 5 that has reached the downstream part of the primary straight portion 21 to the upstream part of the primary straight portion 21. The travel path 2 shown in FIG. 1 further includes a branch straight portion 24 branching from the primary straight portion 21 and merging into a portion different from the primary straight portion 21.

As shown in FIG. 1, the transfer points 3 are defined along the travel path 2. A transfer port at which the transport vehicle 5 transfers the article 11 is disposed at each transfer point 3. Each transfer port includes an article support 31 (refer to FIG. 2) to support the article 11. The article 11 is transferred between the transport vehicle 5 and the article support 31 at the transfer port. The article support 31 is, for example, a load port of a processing device that processes the article 11 (including objects contained in the article 11), a load-unload port of a storage for storing the article 11, or a storage shelf for storing the article 11. Storing herein includes storing temporarily. The article support 31 thus includes a buffer for temporarily retracting the article 11 from the travel path 2. The article support 31 further includes a conveyor or another transferrer for transporting the article 11 to the transfer point 3. In the example shown in FIG. 1, the transfer points 3 are defined on all straight portions. The transfer points 3 may be defined on portions other than the straight portions.

As shown in FIG. 1, the rechargeable points 4 are defined along the travel path 2 as predetermined areas. The power storage 53 in the transport vehicle 5 is recharged when the transport vehicle 5 enters the rechargeable point 4. A charger 41 for charging the power storage 53 (described later) in the transport vehicle 5 is disposed at each rechargeable point 4. The charger 41 can charge the power storage 53 in the transport vehicle 5. The transport vehicle 5 may be recharged at the rechargeable point 4 contactlessly or with contact. In the present embodiment, the charger 41 charges the power storage 53 in the transport vehicle 5 that has stopped at the rechargeable point 4. In the example shown in FIG. 1, the rechargeable points 4 are defined on the primary straight portion 21, the secondary straight portion 22, the return straight portion 23, and the branch straight portion 24. The rechargeable points 4 may be defined at positions other than the primary straight portion 21, the secondary straight portion 22, the return straight portion 23, and the branch straight portion 24. The rechargeable points 4 and the transfer points 3 may overlap each other.

In the example shown in FIG. 1, the transfer points 3 and the rechargeable points 4 are defined at predetermined intervals for ease of explanation. A section between adjacent transfer points 3, between adjacent rechargeable points 4, or between a transfer point 3 and a rechargeable point 4 adjacent to each other is hereafter referred to as one section. The transfer points 3 and the rechargeable points 4 may not be defined at the same predetermined intervals, and the distance between adjacent transfer points 3, between adjacent rechargeable points 4, or between a transfer point 3 and a rechargeable point 4 adjacent to each other may vary at positions.

### 3. Transport Vehicle

The exterior structure of the transport vehicle 5 will be described with reference to FIGS. 2 and 3. The transport vehicle 5 shown in FIG. 2 includes travelers 51 and a body 52. Each traveler 51 includes travel wheels 511 that roll on travel surfaces of the rails 20, and a travel driver 512 (e.g., an electric motor such as a servo motor) that rotates the travel wheels 511. The travel driver 512 drives the travel wheels 511 to rotate, causing the traveler 51 to travel along the rails 20. This causes the transport vehicle 5 to travel along the travel path 2. In this example, the traveler 51 includes guide wheels 513 that roll on guide surfaces of the rails 20. The traveler 51 travels along the rails 20 with the guide wheels 513 in contact with and guided along the guide surfaces of the rails 20.

The travel driver 512 may be a set of drivers that drive multiple drive targets. For example, the traveler 51 may include a switcher that switches the traveling direction of the transport vehicle 5 at the branches 27 (refer to FIG. 1), and the travel driver 512 may drive the switcher in addition to the travel wheels 511. The switcher switches the position of a guided portion included in the traveler 51 between a position at which the guided portion comes in contact with a guide rail extending along the travel path 2 on a first side in the lateral direction Y and a position at which the guided portion comes in contact with the guide rail on a second side in the lateral direction Y.

The body 52 is connected to the travelers 51. In this example, the body 52 is disposed on a lower side Z2 relative to the travelers 51. The body 52 includes a holder 521 that holds the article 11. The article 11 held by the holder 521 is transported by the transport vehicle 5. The body 52 includes a transfer driver (e.g., an electric motor such as a servo motor; not shown) for transferring the article 11 between the transport vehicle 5 and a transfer area (e.g., the article support 31 described later). The holder 521 is driven by the transfer driver to perform a holding operation of holding the article 11 and a releasing operation of releasing the article 11.

The transfer driver may be a set of drivers that drive multiple drive targets. In the example shown in FIG. 2, the body 52 includes a lifter 522 that lifts and lowers the holder 521 and a mover 524 that moves the holder 521 in the lateral direction Y. The transfer driver drives the lifter 522 and the mover 524 in addition to the holder 521. In this example, the lifter 522 lifts the holder 521 by winding wound members 523 (e.g., belts or wires) suspending the holder 521 on a rotator (e.g., a drum; not shown). The lifter 522 lowers the holder 521 by unwinding the wound members 523 from the rotator. In this example, the mover 524 moves the holder 521 supported by the lifter 522 in the lateral direction Y by moving the lifter 522 in the lateral direction Y. The body 52 may include a rotation device that rotates the holder 521 about the vertical axis parallel to the vertical direction Z, and the rotation device may be driven by the transfer driver.

When the article 11 is transferred between the transport vehicle 5 and a transfer port, the transport vehicle 5 travels to the transfer point 3 including the transfer port to be used. The transport vehicle 5 travels with the holder 521 at a reference height H1 (refer to FIG. 2). With the holder 521 at the reference height H1, the holder 521 and the article 11 held by the holder 521 are accommodated in the body 52. The reference height H1 is on an upper side Z1 relative to a transfer height H2 (described later). After reaching the transfer point 3, the transport vehicle 5 transfers the article 11 between the transport vehicle 5 and the article support 31. When the article support 31 is not immediately below the travel path 2 and is at a position shifted in the lateral direction Y from the travel path 2, the transport vehicle 5 moves, with the mover 524, the holder 521 to a position immediately above the article support 31 in the lateral direction Y, and then transfers the article 11.

To transfer the article 11 from the transport vehicle 5 to the article support 31, the holder 521 performs a lowering operation while holding the article 11, the releasing operation to release the article 11, and a lifting operation while holding no article 11 in this order. In the lowering operation, the holder 521 holding the article 11 is lowered by the lifter 522 from the reference height H1 to the transfer height H2. The transfer height H2 (refer to FIG. 2) is determined based on the height of the article support 31. In the releasing operation, the holder 521 releases the article 11. In the lifting operation, the holder 521 holding no article 11 is lifted by the lifter 522 from the transfer height H2 to the reference height H1.

To transfer the article 11 from the article support 31 to the transport vehicle 5, the holder 521 performs the lowering operation while holding no article 11, the holding operation to hold the article 11, and the lifting operation while holding the article 11 in this order. In the lowering operation, the holder 521 holding no article 11 is lowered by the lifter 522 from the reference height H1 to the transfer height H2. In the holding operation, the holder 521 holds the article 11. In the lifting operation, the holder 521 holding the article 11 is lifted by the lifter 522 from the transfer height H2 to the reference height H1.

The internal structure of the transport vehicle 5 will be described with reference to FIG. 4. As shown in FIG. 4, the transport vehicle 5 includes the power storage 53 chargeable with the charger 41, a drive 54 drivable by the electric power stored in the power storage 53, and a controller 55 that controls the drive 54. The transport vehicle 5 travels on the electric power stored in the power storage 53. In the present embodiment, the travel driver 512 drives the travel wheels 511 to rotate using the electric power stored in the power storage 53, causing the travelers 51 to travel along the travel path 2.

The power storage 53 stores electric power. The power storage 53 can be recharged and discharged. The power storage 53 is, for example, a battery, a capacitor, or a combination of a battery and a capacitor. The power storage 53 includes a battery level sensor to detect a battery level. The battery level sensor includes, for example, one or both of a voltage sensor and a current sensor.

In the transport vehicle 5 shown in FIG. 3, the power storage 53 receives electric power contactlessly through feed lines 42 installed along the travel path 2 at the rechargeable points 4. In the present embodiment, the power storage 53 includes a power receiver 53R that receives electric power contactlessly through the feed lines 42. An example of the power receiver 53R is a pickup coil. In the present embodiment, the charger 41 includes the feed lines 42 and a power supply 43 that feeds electric power to the feed lines 42. In the pickup coil as an example of the power receiver 53R, alternating current power is induced by a magnetic field generated around the feed lines 42 receiving alternating current from the power supply 43. The alternating current power is converted to, for example, direct current power and supplied to the power storage 53.

The drive 54 generates a driving force for causing the transport vehicle 5 to travel along the travel path 2. In the present embodiment, the transport vehicle 5 moves the article 11 to transfer the article 11 between the transport vehicle 5 and a transfer point 3. However, a transfer port at the transfer point 3 may move the article 11 to transfer the article 11 between the transport vehicle 5 and the transfer point 3.

The controller 55 controls the drive 54. The controller 55 controls the drive 54 (e.g., the travel driver 512 described above) to cause the transport vehicle 5 to travel along the travel path 2. In the present embodiment, the controller 55 further controls the drive 54 (e.g., the transfer driver described above) to cause the transport vehicle 5 to transfer the article 11 between the transport vehicle 5 and the transfer point 3. The controller 55 and a host controller 61 (described later) each include, for example, an arithmetic processor such as a central processing unit (CPU) and a peripheral circuit such as a memory. The functions of the controller 55 and the host controller 61 are implemented by, for example, hardware such as an arithmetic processor and a program executable on the hardware operating in cooperation with each other.

### 4. Control System

The control system 6 controls the multiple transport vehicles 5. In the present embodiment, as shown in FIG. 4, the control system 6 includes the host controller 61. The host controller 61 may be a set of multiple devices that can communicate with one another. The host controller 61 is connected to the controller 55 in each transport vehicle 5 to allow communication. The controller 55 controls the operation of the transport vehicle 5 in response to a command from the host controller 61.

### 4.1. Transport Command Process and Transport Execution Process

The control system 6 (the host controller 61 in the present embodiment) performs a transport command process for instructing one of the multiple transport vehicles 5 to transport a target article 10 that is an article 11 to be transported, and a transport execution process for causing the transport vehicle 5 to transport the target article 10 based on the transport command process.

To perform the transport command process and the transport execution process, the control system 6 tracks the current position of each of the multiple transport vehicles 5. In the present embodiment, each transport vehicle 5 identifies its current position, and the host controller 61 obtains information about the current position of the transport vehicle 5 from the transport vehicle 5. Although not described in detail, for example, detectable members storing position information may be arranged at multiple positions along the travel path 2. Examples of the detectable members include one-dimensional codes, two-dimensional codes, and radio-frequency (RF) tags. Each transport vehicle 5 reads the position information held by the detectable members to identify its current position. The transport vehicle 5 identifies its current position based on, for example, the read position information and a travel distance after reading the position information. The transport vehicle 5 may identify its current position based on an output from a positioning device such as a global navigation satellite system (GNSS) receiver.

### 4.2. Transport Command Process

In the transport command process, a transport task for transporting the target article 10 is generated and assigned to one of the multiple transport vehicles 5. The transport task specifies, from the multiple transfer points 3, a load point S at which the target article 10 is loaded and an unload point G at which the target article 10 is unloaded. In the example shown in FIG. 1, the load point S and the unload point G are transfer points 3 on the primary straight portion 21. The unload point G is four sections downstream from the load point S. Hereafter, a single transport vehicle 5 or multiple transport vehicles 5 receiving the target article 10 at the load point S and then unloading the target article 10 at the unload point G may be simply referred to as the transport vehicle(s) 5 transporting the target article 10.

The transport task may be generated by the host controller 61 or by another device that can communicate with the host controller 61. The host controller 61 then instructs the transport vehicle 5 to which the transport task is assigned to perform the transport task. The controller 55 in the instructed transport vehicle 5 controls the transport vehicle 5 to perform the transport task. The transport task may be assigned to a transport vehicle 5 at a position near the load

point S. For example, the transport task may be assigned to a transport vehicle 5 at a position upstream from the load point S. When the electric power expected to be used by the transport vehicle 5 for receiving the target article 10 at the load point S and transporting the target article 10 to the unload point G is referred to as an expected power consumption, the transport task may be assigned to a transport vehicle 5 including the power storage 53 with a battery level greater than or equal to the expected power consumption. In this case as well, a relay process (described later) may be performed when the electric power in the transport vehicle 5 is insufficient due to, for example, traffic congestion. In the example shown in FIG. 1, the transport vehicle 5 at a position upstream from the load point S on the primary straight portion 21 transports the target article 10 as a first transport vehicle 5A. This shortens the travel distance of the first transport vehicle 5A, which is the transport vehicle 5 performing the assigned transport task, from the position at the time of transport task assignment to the unload point G through the load point S. The control system 6 can thus easily improve the transport efficiency across the entire facility.

### 4.3. Transport Execution Process

The transport execution process includes performing a power level obtaining process for obtaining the battery level of the power storage 53 in the transport vehicle 5 and a transport path setting process for setting a transport path R that is a travel path of the transport vehicle 5 from the load point S to the unload point G. In the present embodiment, the transport path setting process includes a process in which the control system 6 causes the transport vehicle 5 to travel along the set transport path R. The power level obtaining process and the transport path setting process will be described in detail below.

The power level obtaining process obtains the battery levels of the power storages 53 in the multiple transport vehicles 5 including the first transport vehicle 5A. The control system 6 obtains the battery levels of the power storages 53 in one or more transport vehicles 5 other than the first transport vehicle 5A. The control system 6 may obtain the battery levels of the power storages 53 in transport vehicles 5 on or near the transport path R. This reduces processing load on the control system 6. However, the control system 6 may also obtain the battery levels of the power storages 53 in all transport vehicles 5. This allows the transport path R to be set flexibly by reflecting the battery levels of the power storages 53 in all transport vehicles 5.

The power level obtaining process obtains battery level information indicating the battery level of the power storage 53. The battery level is represented by, for example, a ratio (percentage) of the remaining capacity to a full charge capacity. In this case, the battery level in a fully recharged state is 100%, and the battery level in a fully discharged state is 0%. In the present embodiment, for ease of explanation, the transport vehicle 5 consumes electric power equivalent to 10% of the full charge capacity of the power storage 53 for every section traveled. However, the transport vehicle 5 may not consume electric power equivalent to 10% of the full charge capacity of the power storage 53. For ease of explanation, the ratio of the remaining capacity to the full charge capacity is hereafter simply represented as a battery level in percentage. More specifically, the battery level equivalent to 10% of the full charge capacity of the power storage 53 may be simply referred to as a battery level of 10%.

The battery level of the power storage 53 may be estimated based on, for example, the output voltage of the power storage 53, or the integrated value of the charge power level indicating the power level at which the power storage 53 is charged and the integrated value of the discharge power level indicating the power level at which the power storage 53 is discharged. The battery level of the power storage 53 may also be estimated based on a combination of these. When the battery level of the power storage 53 is estimated by the controller 55 in the transport vehicle 5, the controller 55 transmits the battery level information indicating the estimated battery level to the host controller 61. When the battery level of the power storage 53 is estimated by the host controller 61, the host controller 61 obtains information used for estimating the battery level of the power storage 53 (e.g., information about detection values from the battery level sensor described above) from the transport vehicle 5.

In the transport path setting process, a path connecting the load point S and the unload point G specified in the transport task is set as the transport path R. The control system 6 may set the shortest path from the load point S to the unload point G as the transport path R, or may select the transport path R from multiple candidates. More specifically, in the example shown in FIG. 1, candidates for the transport path R include two paths, or more specifically, the shortest path simply including the primary straight portion 21 from the load point S to the unload point G, and a path to the unload point G through the secondary straight portion 22. In the example shown in FIG. 1, the path simply including the primary straight portion 21 is set as the transport path R.

The control system 6 performs either a regular process for causing the first transport vehicle 5A to solely transport the target article 10, or a relay process for causing multiple transport vehicles 5 including the first transport vehicle 5A to transport the target article 10. The regular process sets the transport path R for the first transport vehicle 5A to solely transport the target article 10. With the first transport vehicle 5A solely transporting the target article 10 in the regular process, for example, the path with the shortest travel distance or the shortest travel time for the first transport vehicle 5A can be easily selected from multiple candidates for the transport path R. Thus, the regular process may be performed preferentially.

### 4.4. Relay Process

The relay process is performed when the first transport vehicle 5A cannot solely transport the target article 10, or when multiple transport vehicles 5 are more useful than a single transport vehicle 5 to transport the target article 10. In the present embodiment, the control system 6 performs the relay process in response to determining that the battery level of the power storage 53 in the first transport vehicle 5A is insufficient to reach the unload point G. In this case, the control system 6 causes the first transport vehicle 5A and one or more transport vehicles 5 other than the first transport vehicle 5A to transport the target article 10. In the present embodiment, the first transport vehicle 5A and a second transport vehicle 5B that is a transport vehicle 5 different from the first transport vehicle 5A transport the target article 10. The first transport vehicle 5A and the second transport vehicle 5B travel along the transport path R to transport the target article 10.

The control system 6 determines, at an appropriate timing, whether to perform the relay process. In the present embodiment, the control system 6 determines whether to perform the relay process at the time when the transport task is assigned. This allows early determination of whether to perform the relay process, facilitating assignment of the second transport vehicle 5B when the relay process is performed. The control system 6 may determine whether to perform the relay process at the time when the first transport vehicle 5A receives the target article 10 at the load point S. By determining whether to perform the relay process at this timing, the transport path R can be defined based on the battery level immediately before the first transport vehicle 5A starts transporting the target article 10. The first transport vehicle 5A can transport the target article 10 appropriately. The control system 6 may determine whether to perform the relay process after the first transport vehicle 5A receives the target article 10 at the load point S. By determining whether to perform the relay process at this timing, the relay process can be performed in response to the power storage 53 in the first transport vehicle 5A having an unexpectedly insufficient battery level. The second transport vehicle 5B thus transports the target article 10 appropriately.

The relay process is performed in place of the regular process when a relay transport criterion is satisfied. In the relay process, multiple transport vehicles 5 transport the target article 10. Thus, the relay transport criterion is determined based on transport conditions of the multiple transport vehicles 5 including the first transport vehicle 5A. The transport conditions include the battery level of the power storage 53 in each of the transport vehicles 5 that are candidates for the first transport vehicle 5A, the battery level of the power storage 53 in the first transport vehicle 5A, or the time taken to transport the target article 10. Three specific examples each satisfying the relay transport criterion are described below. Each of the examples described below may be used as a single relay transport criterion, or a combination of one or more of these may be used as relay transport criteria.

In a first specific example of the relay transport criterion, the transport condition is the battery level of the power storage 53 in each of the transport vehicles 5 that are candidates for the first transport vehicle 5A. In this case, the control system 6 defines the relay transport criterion as whether the power storage 53 in any of the transport vehicles 5 that are candidates for the first transport vehicle 5A has a battery level sufficient to solely transport the target article 10 to the unload point G. When the relay transport criterion is defined as described above and no power storage 53 in the transport vehicles 5 has a battery level sufficient to solely transport the transport target, the control system 6 determines that the relay transport criterion is satisfied and performs the relay process. This is an example in which the first transport vehicle 5A cannot solely transport the target article 10.

In a second specific example of the relay transport criterion, the transport condition is the battery level of the power storage 53 in the first transport vehicle 5A. In this case, the control system 6 defines the relay transport criterion as whether the power storage 53 in the first transport vehicle 5A has a battery level sufficient to transport the target article 10. When the battery level of the power storage 53 in the first transport vehicle 5A is insufficient to transport the target article 10, the control system 6 determines that the relay transport criterion is satisfied and performs the relay process. For example, the relay process is performed when multiple transport vehicles 5 cause congestion and the battery level of the power storage 53 in the first transport vehicle 5A is below a level that allows the first transport vehicle 5A to travel to the unload point G. This is an example in which the first transport vehicle 5A cannot solely transport the target article 10.

In a third specific example of the relay transport criterion, the transport condition is the time taken to transport the target article 10. In this case, the control system 6 calculates and compares a regular transport time taken for the regular process and a relay transport time taken for the relay process. When the relay transport time is shorter than the regular transport time, the control system 6 determines that the relay transport criterion is satisfied and performs the relay process. This is an example in which multiple transport vehicles 5 are more useful than a single transport vehicle 5 to transport the target article 10.

The relay process includes, as shown in FIGS. 1, 5, and 6, a relay transport process for causing the first transport vehicle 5A to transport the target article 10 to a relay point T, and a takeover transport process for causing the second transport vehicle 5B to take over the transportation of the target article 10 transported to the relay point T.

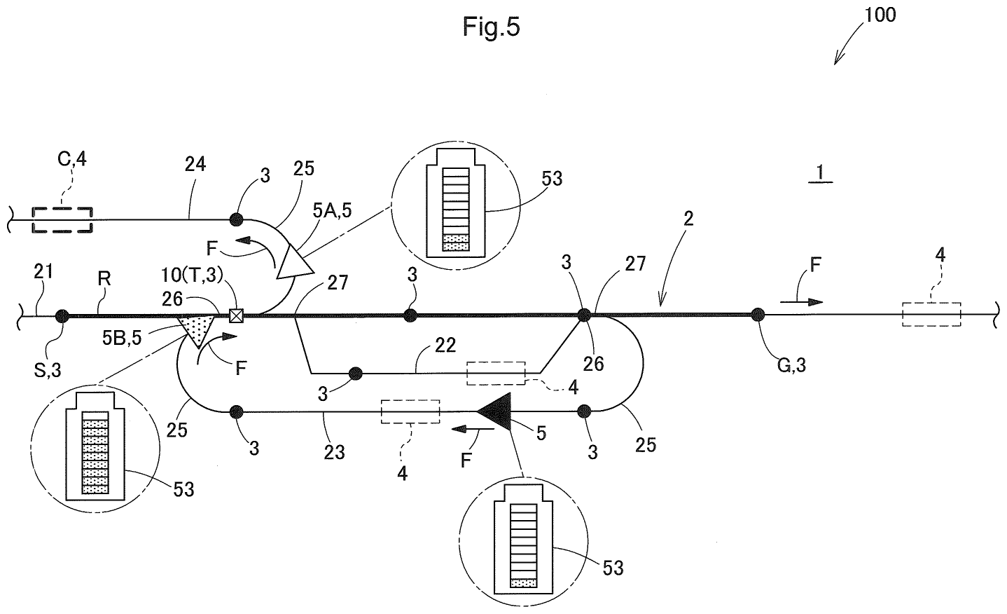

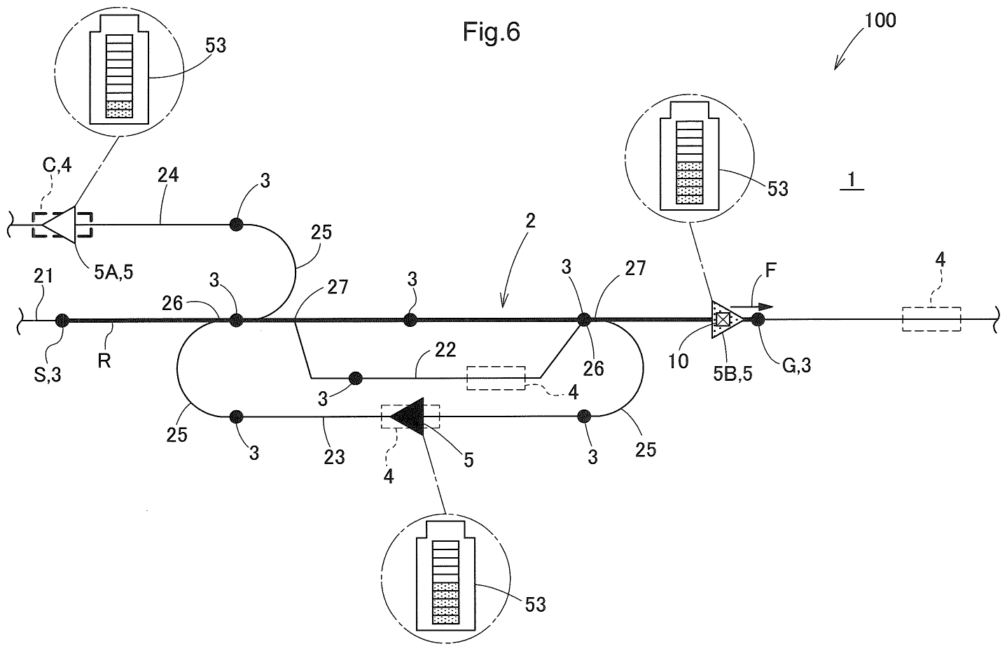

In the relay transport process, as shown in FIGS. 1 and 5, the control system 6 causes the first transport vehicle 5A to travel to the relay point T to transfer the target article 10 to the transfer port at the relay point T. The relay point T is selected from the multiple transfer points 3. In the relay transport process, a recharge point C for recharging the power storage 53 in the first transport vehicle 5A is also selected from the multiple rechargeable points 4. As shown in FIG. 6, the first transport vehicle 5A transports the target article 10 to the transfer port at the relay point T and then travels toward the recharge point C. After the first transport vehicle 5A reaches the recharge point C, the power storage 53 in the first transport vehicle 5A is recharged. After transporting the target article 10 to the transfer port at the relay point T, the first transport vehicle 5A may transport another target article 10 without traveling toward the recharge point C. This allows the electric power stored in the power storage 53 in the first transport vehicle 5A to be consumed efficiently.

In the takeover transport process, the second transport vehicle 5B transports the target article 10 to the unload point G. When the relay point T is selected in the takeover transport process, the control system 6 causes the second transport vehicle 5B to travel to the relay point T and receive the target article 10 from the transfer port at the relay point T, and then causes the second transport vehicle 5B to travel to the unload point G, as shown in FIGS. 5 and 6.

The relay transport process and the takeover transport process will now be described in detail with specific examples. In the relay process, the control system 6 basically performs an example basic relay transport process that is an example of the relay transport process. The control system 6 may also perform, in combination with the example basic relay transport process, example relay transport processes other than the example basic relay transport process, and an example takeover transport process. The control system 6 may also perform example relay transport processes other than the example basic relay transport process in combination with the example takeover transport process unless any contradiction arises.

### Example Basic Relay Transport Process

In the relay transport process shown in FIGS. 1 and 5, the control system 6 selects a relay point T and a recharge point C that satisfy a reachability condition. The reachability condition is satisfied when the first transport vehicle 5A can reach the recharge point C through the relay point T with the battery level of the power storage 53 in the first transport vehicle 5A. For example, as shown in FIG. 1, when the power storage 53 has a battery level of 30% in the first transport vehicle 5A receiving the target article 10 at the load point S, the relay point T and the recharge point C are set within three sections downstream from the current position of the first transport vehicle 5A.

In the relay transport process, as shown in FIG. 1, a transfer point 3 closest to the unload point G on the transport path R satisfies the reachability condition and is selected as the relay point T. In the example shown in FIG. 1, a transfer point 3 at a position one section downstream from the current position of the first transport vehicle 5A is set as the relay point T.

The recharge point C is selected from the rechargeable points 4 within a selection range A2 from the relay point T. The selection range A2 is defined to include areas that satisfy the reachability condition on the transport path R and out of the transport path R. In the example shown in FIG. 1, the selection range A2 includes the rechargeable points 4 on the secondary straight portion 22 and the branch straight portion 24. In the example shown in FIG. 5, the rechargeable point 4 on the branch straight portion 24 is set as the recharge point C for the first transport vehicle 5A. Thus, after transferring the target article 10 to the transfer port at the relay point T, the first transport vehicle 5A travels toward the recharge point C.

### Example Takeover Transport Process

The second transport vehicle 5B that has unloaded the target article 10 at the unload point G may have, at or near the unload point G, a battery level insufficient to travel. The takeover transport process described in this example prevents the second transport vehicle 5B from having an insufficient battery level at or near the unload point G to allow the second transport vehicle 5B to be appropriately recharged at a rechargeable point 4.

In the takeover transport process shown in FIGS. 1 and 6, the control system 6 selects, as the second transport vehicle 5B, a transport vehicle 5 with the power storage 53 having a battery level higher than or equal to a takeover reference value. The takeover reference value is a battery level that allows the second transport vehicle 5B to transport the target article 10 from the relay point T to the unload point G and then travel from the unload point G to the closest rechargeable point 4. In the example shown in FIG. 1, the distance from the relay point T to the unload point G is three sections, and the distance from the unload point G to the closest rechargeable point 4 is one section. Thus, the takeover reference value is set to a battery level that allows travel through four sections from the relay point T to the rechargeable point 4 closest to the unload point G, or more specifically, to a battery level of 40%.

The takeover reference value may include the power level for the second transport vehicle 5B to travel from the current position at the time when the control system 6 selects the second transport vehicle 5B to the relay point T. In the example shown in FIG. 1, the distance from the current position of the second transport vehicle 5B to the relay point T is two sections. Thus, the takeover reference value is set to the battery level that allows travel from the current position of the second transport vehicle 5B shown in FIG. 1 to the rechargeable point 4 closest to the unload point G, or more specifically to a battery level of 60%. This structure allows the second transport vehicle 5B to transport the target article 10 from the relay point T to the unload point G without a recharge after being selected. In the example shown in FIG. 1, the power storage 53 in the second transport vehicle 5B has a battery level of 100%. As shown in FIG. 6, the power storage 53 in the second transport vehicle 5B thus has a battery level of 50% when the second transport vehicle 5B reaches the unload point G after traveling through the primary straight portion 21. The second transport vehicle 5B can thus reach the rechargeable point 4 closest to the unload point G appropriately.

### Example Relay Transport Process 1

When the relay point T is set to a location with a greater traffic volume of transport vehicles 5, the target article 10 unloaded at the relay point T may obstruct the travel of subsequent transport vehicles 5. An example relay transport process 1 is an example of the relay transport process for preventing such situations.

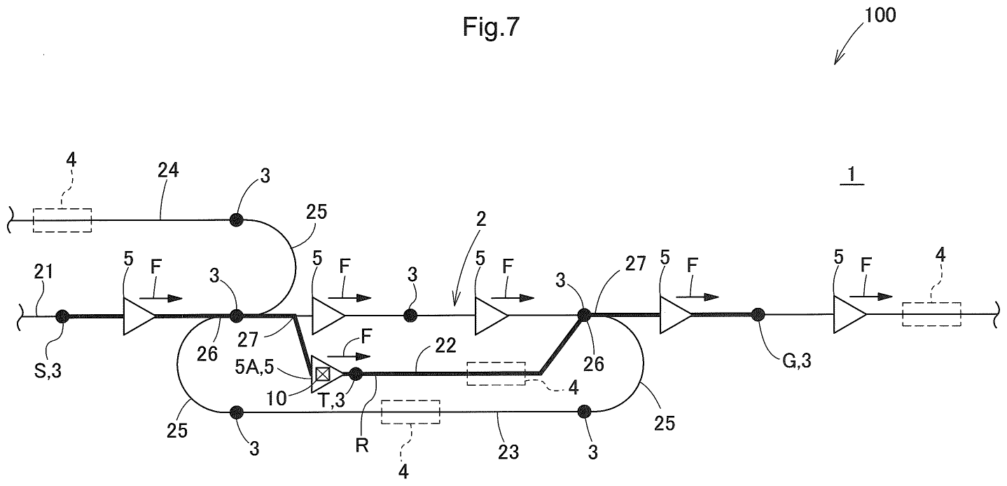

As shown in FIG. 7, when the relay point T is selectable from multiple transfer points 3 in the relay transport process, the control system 6 excludes, from candidates for the relay point T, the transfer points 3 on a path with a traffic volume of transport vehicles 5 greater than or equal to a set value. The traffic volume is defined as, for example, the number of vehicles passing per unit time, the ratio of the time of traffic congestion involving multiple transport vehicles 5, or the frequency of traffic congestion. The set value of the traffic volume set in this manner allows, for example, a transfer point 3 to be selected as the relay point T on a path of the travel path 2 other than a major path that is a path traveled by a greater number of transport vehicles 5 on average than other paths. In the example shown in FIG. 7, the primary straight portion 21 is the major path. The control system 6 thus sets, as the transport path R, a path including the secondary straight portion 22 that is not the major path. The control system 6 then selects the transfer point 3 closest to the unload point G on the transport path R as the relay point T. In the example shown in FIG. 7, the control system 6 selects the transfer point 3 on the secondary straight portion 22 as the relay point T.

### Example Relay Transport Process 2

When the recharge point C is set to a location with a greater traffic volume of transport vehicles 5, a transport vehicle 5 being recharged at the recharge point C may obstruct the travel of subsequent transport vehicles 5. An example relay transport process 2 is an example of the relay transport process for preventing such situations.

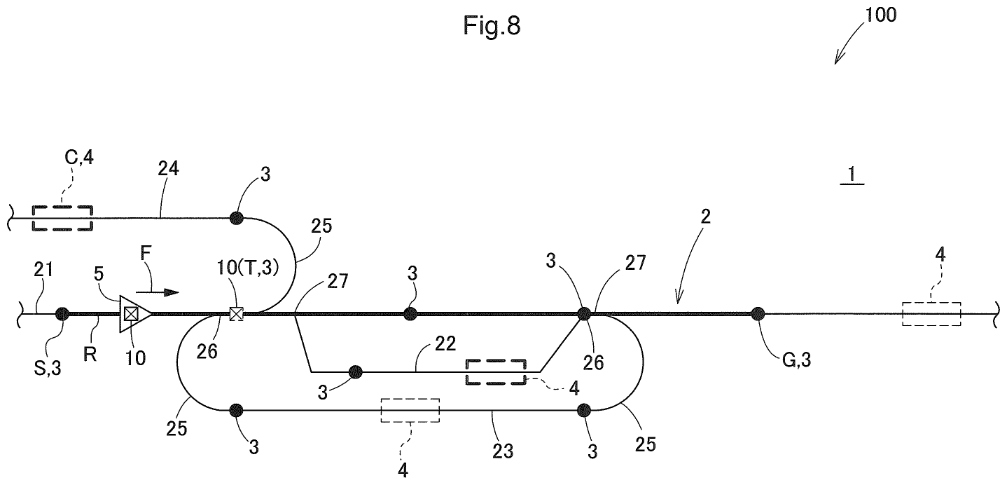

In the relay transport process, when the recharge point C is selectable from multiple rechargeable points 4 as shown in FIG. 8, the control system 6 selects, as the recharge point C, a rechargeable point 4 on a path with a traffic volume of transport vehicles 5 less than or equal to a set value. In the example shown in FIG. 8, the primary straight portion 21 is the major path in the same manner as described in the example relay transport process 1. Thus, in the example shown in FIG. 8, when the transport path R, the relay point T, and the selection range A2 are the same as in the example in FIG. 1, the control system 6 sets, as the recharge point C, a rechargeable point 4 on the secondary straight portion 22 or the branch straight portion 24 that is not the major path. In the example shown in FIG. 8, the rechargeable point 4 on the branch straight portion 24 is selected as the recharge point C.

### Example Relay Transport Process 3

When the recharge point C is set to a location on the path of transport vehicles 5 traveling from the relay point T to the unload point G, a transport vehicle 5 being recharged at the recharge point C may obstruct the travel of a subsequent transport vehicle 5 that has received the target article 10 at the relay point T. An example relay transport process 3 is an example of the relay transport process for preventing such situations.

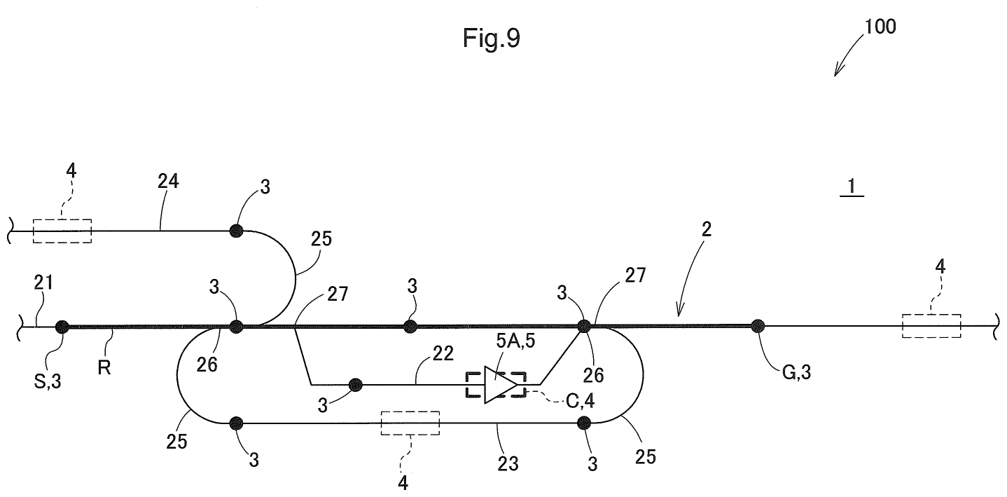

In the relay transport process, as shown in FIG. 9, the control system 6 excludes, from candidates for the recharge point C, points on the path of transport vehicles 5 traveling from the relay point T to the unload point G. In the example shown in FIG. 9, when the transport path R, the relay point T, and the selection range A2 are the same as in the example in FIG. 1, rechargeable points 4 upstream from the unload point G on the primary straight portion 21, or in other words, rechargeable points 4 on the transport path R, are excluded from candidates for the recharge point C. The recharge point C is then selected from rechargeable points 4 on the secondary straight portion 22 and the branch straight portion 24. In the example shown in FIG. 9, a rechargeable point 4 on the secondary straight portion 22 is selected as the recharge point C. The first transport vehicle 5A is being recharged at the recharge point C.

### Example Relay Transport Process 4

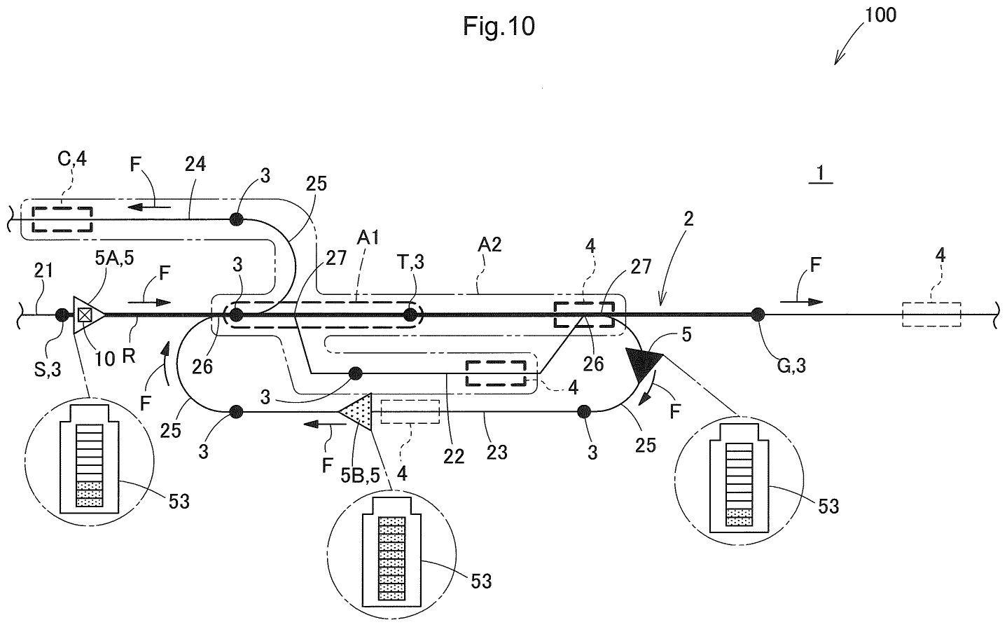

Selecting the relay point T from multiple candidates may facilitate efficient transportation of the article 11 across the entire transport facility 100. An example relay transport process 4 is an example of the relay transport process for such cases. For ease of explanation, in the travel area 1 shown in FIG. 10, a rechargeable point 4 is one section upstream from the unload point G on the primary straight portion 21, unlike the transfer point 3 in the example in FIG. 1.

In the relay transport process, as shown in FIG. 10, the control system 6 selects, as the relay point T, one of the transfer points 3 within a setting range A1 from the transport path R. The setting range A1 is defined to include areas on the transport path R that satisfy the reachability condition. The setting range A1 shown in FIG. 10 includes transfer points 3 on the primary straight portion 21 within two sections downstream from the current position of the first transport vehicle 5A. In the example shown in FIG. 10, a transfer point 3 at a position two sections downstream from the current position of the first transport vehicle 5A is set as the relay point T.

### 5. Other Embodiments

A transport facility 100 according to other embodiments will now be described.
(1) In the present embodiment, the travel path 2 is physically defined. However, the travel path 2 may be defined virtually. Examples of the transport vehicles 5 that travel along the virtual travel path 2 include trackless transport vehicles such as automated guided vehicles (AGVs). In this case, detectable members, such as magnetic tape, two-dimensional codes, or RF tags, that are detectable by the transport vehicles 5 may be installed on, for example, a floor surface to define the travel path 2 virtually. In this case, the travel path 2 is, for example, virtually defined along the detectable members or by connecting the multiple detectable members.
(2) In the present embodiment, the rails 20 defining the travel path 2 are hung from the ceiling 1c. However, the rails 20 defining the travel path 2 may be disposed on, for example, the floor surface, rather than being hung from the ceiling 1c. Additionally, in the present embodiment, the travel path 2 is defined by the rails 20. However, the travel path 2 may have a different structure and may be physically defined based on the shapes of aisles along which the transport vehicles 5 travel. In this case, the travel path 2 is physically defined by, for example, structures separating the aisles.
(3) In the present embodiment, the control system 6 includes the host controller 61 and the controller 55 (the controller 55 in the respective transport vehicles 5). However, the control system 6 may include the host controller 61 alone. The control system 6 may include, without including the host controller 61, the controllers 55 in the respective transport vehicles 5 that are connected to one another to allow communication and operate in cooperation with one another.
(4) In the present embodiment, the charger 41 at each rechargeable point 4 charges the power storage 53 in the transport vehicle 5 that has stopped at the rechargeable point 4. However, the charger 41 may charge the power storage 53 in the transport vehicle 5 that is traveling. The power storage 53 in the transport vehicle 5 that has stopped at the rechargeable point 4 may be replaced with another power storage 53. In this case, the rechargeable point 4 recharges the power storage 53 removed from the transport vehicle 5. The recharged power storage 53 is attached to another transport vehicle 5 that has stopped at the rechargeable point 4 subsequently.
(5) In the present embodiment, the travel area 1 includes the multiple rechargeable points 4. However, the travel area 1 may include a power feed area that feeds electric power to the power storage 53 or the travel driver 512, and a non-power feed area that feeds no electric power. In this case, feed lines 42 are arranged in the power feed area. The transport vehicle 5 travels while receiving power from the feed lines 42.
(6) In the present embodiment, the control system 6 performs each of the relay transport process and the takeover transport process once. However, the relay transport process and the takeover transport process may be performed, rather than once, as many times as appropriate for the battery levels of the power storages 53 in the transport vehicles 5 assigned for the relay transport process. In other words, the control system 6 may perform another relay transport process and another takeover transport process in response to determining that the battery level of the power storage 53 in the second transport vehicle 5B is insufficient for the second transport vehicle 5B to reach the unload point G. In this case, the control system 6 performs the relay transport process for the second transport vehicle 5B, and the takeover transport process for a third transport vehicle different from the second transport vehicle 5B. The control system 6 performing the takeover transport process for the third transport vehicle may cause the third transport vehicle to travel along the transport path R defined in setting the transport task. The control system 6 may define a new transport path R different from the transport path R defined in setting the transport task to cause the third transport vehicle to travel along the newly defined transport path R.
(7) In the present embodiment, when the relay point T is selectable from multiple transfer points 3 in the relay transport process, the control system 6 excludes, from candidates for the relay point T, the transfer points 3 on a path with a traffic volume of transport vehicles 5 greater than or equal to a set value. In this example, when the traffic volume of transport vehicles 5 is greater than or equal to the set value across the transport path R, the control system 6 may select a transfer point 3 closest to the unload point G on the transport path R as the relay point T instead of excluding the transfer points 3 on a path with a traffic volume of transport vehicles 5 greater than or equal to the set value from candidates for the relay point T.
(8) The structure described in each of the above embodiments may be combined with other structures described in the other embodiments unless any contradiction arises. The embodiments described herein are merely illustrative in all aspects and may be modified variously as appropriate without departing from the spirit and scope of the disclosure.

### 6. Overview of Present Embodiment

An overview of the transport facility according to the embodiments described above is provided below.

A transport facility includes a plurality of transport vehicles that travel in a travel area to transport articles, and a control system that controls the plurality of transport vehicles. Each of the plurality of transport vehicles includes a power storage to travel on electric power stored in the power storage. The travel area includes a plurality of rechargeable points and a plurality of transfer points. Each of the plurality of rechargeable points includes a charger that charges the power storage. Each of the plurality of transfer points includes a transfer port at which the plurality of transport vehicles transfer the articles. The control system performs a transport command process, a relay transport process, and a takeover transport process. The transport command process generates, to transport a target article being one of the articles, a transport task specifying a load point at which the target article is loaded and an unload point at which the target article is unloaded, and assigns the transport task to a first transport vehicle among the plurality of transport vehicles. The relay transport process selects a relay point from the plurality of transfer points in response to determining that a battery level of the power storage in the first transport vehicle is insufficient for the first transport vehicle to reach the unload point, selects, from the plurality of rechargeable points, a recharge point at which the power storage in the first transport vehicle is recharged, and causes the first transport vehicle to travel to the relay point and transfer the target article to the transfer port at the relay point. The takeover transport process selects, from the plurality of transport vehicles, a second transport vehicle different from the first transport vehicle in response to the relay point being selected, and causes the second transport vehicle to travel to the relay point, receive the target article from the transfer port at the relay point, and then travel to the unload point. In the relay transport process, the control system selects, as the relay point, a transfer point satisfying a condition that the first transport vehicle reaches the recharge point through the relay point with the battery level of the power storage in the first transport vehicle and being closest to the unload point on a transport path being a travel path of a transport vehicle of the plurality of transport vehicles from the load point to the unload point.

In this structure, when the battery level of the power storage in the transport vehicle assigned for the transport task is insufficient for the single transport vehicle to transport the target article to the unload point, the target article can be transported to the unload point with multiple transport vehicles. This structure also allows the first transport vehicle to fully use the electric power stored in the power storage in the first transport vehicle to transport the target article as close to the unload point as possible. This allows the second transport vehicle to save the consumption of the electric power stored in its power storage, facilitating efficient transportation of the articles across the entire transport facility.

The control system may select the recharge point from rechargeable points of the plurality of rechargeable points within a selection range from the relay point.

In this structure, the recharge point may be selected from multiple candidates. In this case, a candidate rechargeable point can be selected as the recharge point to allow the first transport vehicle to use a relatively smaller amount of electric power stored in its power storage and allow efficient transportation of the articles across the entire transport facility.

In the takeover transport process, the control system may select, as the second transport vehicle, a transport vehicle of the plurality of transport vehicles. The transport vehicle selected as the second transport vehicle may include the power storage having a battery level higher than or equal to a level allowing the transport vehicle to transport the target article from the relay point to the unload point and then travel to, among the plurality of rechargeable points, a rechargeable point closest to the unload point.

This structure allows two transport vehicles, or more specifically, the first transport vehicle and the second transport vehicle, to transport the target article from the load point to the unload point. This structure also prevents each of the first transport vehicle and the second transport vehicle from stopping before reaching a rechargeable point due to an insufficient battery level of the power storage in each of the first transport vehicle and the second transport vehicle.

In the relay transport process, when the relay point is selectable from more than one of the plurality of transfer points, the control system may exclude, from candidates for the relay point, a transfer point on a path with a traffic volume of the plurality of transport vehicles greater than or equal to a set value, and select, as the relay point, a transfer point closest to the unload point.

In this structure, the transport vehicle stops at the relay point to transfer the target article, reducing the likelihood of the transport vehicle that has stopped at the relay point obstructing the travel of other transport vehicles. This facilitates efficient transportation of the articles across the entire transport facility.

In the relay transport process, when the recharge point is selectable from more than one of the plurality of rechargeable points, the control system may select, as the recharge point, a rechargeable point on a path with a traffic volume of the plurality of transport vehicles less than or equal to a set value.

In this structure, the transport vehicle stops at the recharge point to recharge the power storage, reducing the likelihood of the transport vehicle that has stopped at the recharge point obstructing the travel of other transport vehicles. This facilitates efficient transportation of the articles across the entire transport facility.

In the relay transport process, the control system may exclude, from candidates for the recharge point, a point on a path of the transport vehicle from the relay point to the unload point.

This structure reduces the likelihood of the first transport vehicle that has stopped at the recharge point obstructing the travel of the second transport vehicle after the takeover transport process. This facilitates efficient transportation of the articles across the entire transport facility.

### INDUSTRIAL APPLICABILITY

The technique according to one or more embodiments of the disclosure can be used in a transport facility including multiple transport vehicles that travel in a travel area to transport articles and a control system that controls the transport vehicles.

What is claimed is:

1. A transport facility, comprising:
a plurality of transport vehicles configured to travel in a travel area to transport articles; and
a control system configured to control the plurality of transport vehicles, and
wherein:
each of the plurality of transport vehicles comprises a power storage to travel on electric power stored in the power storage,
the travel area comprises a plurality of rechargeable points and a plurality of transfer points, each of the plurality of rechargeable points comprising a charger configured to charge the power storage, and each of the plurality of transfer points comprising a transfer port at which the plurality of transport vehicles transfer the articles,
the control system is configured to perform:
a transport command process for generating, to transport a target article being one of the articles, a transport task specifying a load point at which the target article is loaded and an unload point at which the target article is unloaded, and assigning the transport task to a first transport vehicle among the plurality of transport vehicles,
a relay transport process for selecting a relay point from the plurality of transfer points in response to determining that a battery level of the power storage in the first transport vehicle is insufficient for the first transport vehicle to reach the unload point, selecting, from the plurality of rechargeable points, a recharge point at which the power storage in the first transport vehicle is recharged, and causing the first transport vehicle to travel to the relay point and transfer the target article to the transfer port at the relay point, and
a takeover transport process for selecting, from the plurality of transport vehicles, a second transport vehicle different from the first transport vehicle in response to the relay point being selected, and causing the second transport vehicle to travel to the relay point, receive the target article from the transfer port at the relay point, and then travel to the unload point,
in the relay transport process, the control system is configured to select, as the relay point, a transfer point satisfying a condition that the first transport vehicle reaches the recharge point through the relay point with the battery level of the power storage in the first transport vehicle and being closest to the unload point on a transport path being a travel path of a transport vehicle of the plurality of transport vehicles from the load point to the unload point.

2. The transport facility according to claim 1, wherein:
the control system selects the recharge point from rechargeable points of the plurality of rechargeable points within a selection range from the relay point.

3. The transport facility according to claim 1, wherein:
in the takeover transport process, the control system selects, as the second transport vehicle, a transport vehicle of the plurality of transport vehicles, the transport vehicle selected as the second transport vehicle includes the power storage having a battery level higher than or equal to a level allowing the transport vehicle to transport the target article from the relay point to the unload point and then travel to, among the plurality of rechargeable points, a rechargeable point closest to the unload point.

4. The transport facility according to claim 1, wherein:
in the relay transport process, when the relay point is selectable from more than one of the plurality of transfer points, the control system excludes, from candidates for the relay point, a transfer point on a path with a traffic volume of the plurality of transport vehicles greater than or equal to a set value, and selects, as the relay point, a transfer point closest to the unload point.

5. The transport facility according to claim 1, wherein:
in the relay transport process, when the recharge point is selectable from more than one of the plurality of rechargeable points, the control system selects, as the recharge point, a rechargeable point on a path with a traffic volume of the plurality of transport vehicles less than or equal to a set value.

6. The transport facility according to claim 1, wherein:
in the relay transport process, the control system excludes, from candidates for the recharge point, a point on a path of the transport vehicle from the relay point to the unload point.
